(19) United States
(12) Patent Application Publication
(10) Pub. No.: US 2011/0291572 A1
(43) Pub. Date: Dec. 1, 2011

(54) Display Drivers

(75) Inventors: Jeremy Burroughes, Cambridge (GB); Stephen Coats, Cambridgeshire (GB); Haydn Gregory, Cambridge (GB); Euan Smith, Cambridgeshire (GB); Julian Carter, Cambridgeshire (GB)

(73) Assignee: CAMBRIDGE DISPLAY TECHNOLOGY LIMITED, Cambridgeshire (GB)

(21) Appl. No.: 13/123,845

(22) PCT Filed: Oct. 21, 2009
(86) PCT No.: PCT/GB2009/002511

§ 371 Date: Aug. 18, 2011

(30) Foreign Application Priority Data
Oct. 23, 2008 (GB) 0819449.0
Jan. 15, 2009 (GB) 0900616.4

(51) Int. Cl. H05B 37/02; H05K 13/00; H05K 3/30; H05B 37/00

(52) U.S. Cl. 315/152; 315/312; 29/592.1; 29/832

(57) ABSTRACT

An active matrix display comprises a display area of the matrix comprising drive circuitry including a control circuit comprising chiplets outside the display area. The output of the control circuit is distributed among the plurality of chiplets. This arrangement is advantageous in that the chiplets allow for a much smaller fan-in and fan-out structure, thus allowing a much larger percentage of the substrate to be devoted to display area.

### BACKGROUND

Recent years have seen very substantial growth in the market for displays as the quality of displays improves, their cost falls, and the range of applications for displays increases. This includes both large area displays such as for TVs or computer monitors and smaller displays for portable devices.

The most common classes of display presently on the market are liquid crystal displays and plasma displays although displays based on organic light-emitting diodes (OLEDs) are now increasingly attracting attention due to their many advantages including low power consumption, light weight, wide viewing angle, excellent contrast and potential for flexible displays.

The basic structure of an OLED is a light emissive organic layer, for instance a film of a poly(p-phenylenevinylene) (“PPV”) or polyfluorene, sandwiched between a cathode for injecting negative charge carriers (electrons) and an anode for injecting positive charge carriers (holes) into the organic layer. The electrons and holes combine in the organic layer generating photons. In WO90/13148 the organic light-emissive material is a conjugated polymer. In U.S. Pat. No. 4,539,507 the organic light-emissive material is of the class known as small molecule materials, such as (8-hydroxyquinoline) aluminium (“Alq3”). In a practical device one of the electrodes is transparent, to allow the photons to escape the device.

A typical organic light-emissive device (“OLED”) is fabricated on a glass or plastic substrate coated with a transparent anode such as indium-tin-oxide (“ITO”). A layer of a thin film of at least one electroluminescent organic material covers the first electrode. Finally, a cathode covers the layer of electroluminescent organic material. The cathode is typically a metal or alloy and may comprise a single layer, such as aluminium, or a plurality of layers such as calcium and aluminium. In operation, holes are injected into the device through the anode and electrons are injected into the device through the cathode. The holes and electrons combine in the organic electroluminescent layer to form an exciton which then undergoes radiative decay to give light. The device may be pixellated with red, green and blue electroluminescent subpixels in order to provide a full colour display.

Full colour liquid crystal displays typically comprise a white-emitting backlight, and light emitted from the device is filtered through red, green and blue colour filters after passing through the LC layer to provide the desired colour image.

A full colour display may be made in the same way by using a white or blue OLED in combination with colour filters. Moreover, it has been demonstrated that use of colour filters with OLEDs even when the pixels of the device already comprises red, green and blue subpixels can be beneficial. In particular, aligning red colour filters with red electroluminescent subpixels and doing the same for green and blue subpixels and colour filters can improve colour purity of the display (for the avoidance of doubt, “pixel” as used herein may refer to a pixel that emits only a single colour or a pixel comprising a plurality of individually addressable subpixels that together enable the pixel to emit a range of colours).

Downconversion, by means of colour change media (CCMs) for absorption of emitted light and reemission at a desired longer wavelength or band of wavelengths, can be used as an alternative to, or in addition to, colour filters.

One way of addressing displays such as LCDs and OLEDs is by use of an “active matrix” arrangement in which individual pixel elements of a display are activated by an associated thin-film transistor. The active matrix backplane for such displays can be made with amorphous silicon (a-Si) or low temperature polysilicon (LIPS). LIPS has high mobility but can be non-uniform and requires high processing temperatures which limits the range of substrates that it can be used with. Amorphous silicon does not require such high processing temperatures, however its mobility is relatively low, and can suffer from non-uniformities during use due to aging effects. Moreover, backplanes formed from either LIPS or a-Si both require processing steps such as photolithography, cleaning and annealing that can damage the underlying substrate. In the case of LIPS, in particular, a substrate that is resistant to these high-energy processes must be selected. An alternative approach to patterning is disclosed in, for example, Rogers et al, Appl. Phys. Lett. 2004, 84(26), 5398-5400; Rogers et al Appl. Phys. Lett. 2006, 88, 213101- and Benkendorfer et al, Compound Semiconductor, June 2007, in which silicon on an insulator is patterned using conventional methods such as photolithography into a plurality of elements (hereinafter referred to as “chiplets”) which are then transferred to a device substrate. The transfer printing process takes place by bringing the plurality of chiplets into contact with an elastomeric stamp which has surface chemical functionality that causes the chiplets to bind to the stamp, and then transferring the chiplets to the device substrate. In this way, chiplets carrying micro- and nano-scale structures such as display driving circuitry can be transferred with good registration onto an end substrate which does not have to tolerate the demanding processes involved in silicon patterning.

### SUMMARY OF THE INVENTION

According to one aspect of the invention, there is provided a method of manufacturing a control circuit for active matrix display, wherein the control circuit comprises a plurality of chiplets, the method comprising: positioning the control circuit outside the display area; and distributing a plurality of outputs of the control circuit to the display area drive circuitry among the plurality of chiplets.

Throughout this specification, the term “control circuit” is used to refer to circuitry for programming the drive circuitry; “drive circuitry” is used to refer to circuitry for directly driving pixels of the display; and “display area” is used to refer to area defined by pixels of the display and associated drive circuitry.

Preferably, the method further comprises a step of patterning the chiplets on an insulator.

Preferably, the method further comprises a step of transferring the chiplets to a device substrate via a transfer printing process.

Preferably, the method further comprises a step of bringing the plurality of chiplets into contact with an elastomeric stamp which has surface chemical functionality that causes the chiplets to binds to the stamp, and transferring the chiplets to the device substrate.

In one preferred embodiment, the drive circuitry comprises a-Si or LTPS. In another preferred embodiment, the drive circuitry comprises chiplets.

According to an embodiment of the invention, there is provided an active matrix display comprising: a display area of the matrix comprising drive circuitry; a control circuit comprising chiplets outside the display area, wherein the output of the control circuit is distributed among the plurality of chiplets.

Preferably the active matrix display further comprises an optical sensor for ambient light detection.

According to one embodiment, there is a reduction in the substrate area lost to fan-in and fan-out connections through the use of an array of driver chiplets driven by a driver located outside of the active display matrix area.

Further advantages and novel features can be found in the appended claims.

### BRIEF DESCRIPTION OF THE DRAWINGS

For a better understanding of the invention and as to how the same may be carried into effect, reference will now be made, by way of example only, to the accompanying drawings, in which:

FIG. 1 illustrates a device wherein the device is formed by firstly forming an anode on a substrate followed by deposition of an electroluminescent layer and a cathode;

FIG. 2A shows an example of a prior art active matrix display and driving circuitry; and

FIG. 2B shows an active matrix display configuration according to an embodiment of the present invention.

### DETAILED DESCRIPTION

### Chiplet Material

The chiplets may be formed from semiconductor wafer sources, including bulk semiconductor wafers such as single crystalline silicon wafers, polycrystalline silicon wafers, germanium wafers; ultra thin semiconductor wafers such as ultra thin silicon wafers; doped semiconductor wafers such as p-type or n-type doped wafers and wafers with selected spatial distributions of dopants (semiconductor on insulator wafers such as silicon on insulator (e.g. Si—SiO2, SiGe); and semiconductor on substrate wafers such as silicon on substrate wafers and silicon on insulator. In addition, printable semiconductor elements of the present invention may be fabricated from a variety of nonwafer sources, such as a thin films of amorphous, polycrystalline and single crystal semiconductor materials (e.g. polycrystalline silicon, amorphous silicon, polycrystalline GaAs and amorphous GaAs) that is deposited on a sacrificial layer or substrate (e.g. SiN or SiO2) and subsequently annealed, and other bulk crystals, including, but not limited to, graphite, MoSe2 and other transition metal chalcogenides, and yttrium barium copper oxide.

The chiplets may be formed by conventional processing means known to the skilled person.

Preferably, each driver or LED chiplet is up to 500 microns in length, preferably between about 15-250 microns, and preferably about 5-50 microns in width, more preferably 5-10 microns.

### Transfer Process

The stamp used in transfer printing is preferably a PDMS stamp.

The surface of the stamp may have a chemical functionality that causes the chiplets to reversibly bind to the stamp and lift off the donor substrate, or may bind by virtue of, for example, van der Waals force. Likewise upon transfer to the end substrate, the chiplets adhere to the end substrate by van der Waals force and/or by an interaction with a chemical functionality on the surface of the end substrate, and as a result the stamp may be delaminated from the chiplets.

### Chiplet and Display Integration

The chiplets patterned with drive circuitry for addressing pixels or subpixels of a display may be transfer-printed onto a substrate carrying tracking for connection of the chiplets to a power source and, if required, drivers outside the display area for programming the chiplets.

To ensure accurate transfer onto a prepared end substrate, the stamp and end substrate may be registered by means known to the skilled person, for example by providing alignment marks on the substrate.

Alternatively, tracking for connection of the chiplets may be applied after the chiplets have been transfer printed.

In the case where the chiplets drive a display such as an LCD or OLED display, the backplane comprising the chiplets is preferably coated with a layer of insulating material to form a planarisation layer onto which the display is constructed. Electrodes of the display device are connected to the output of the chiplets by means of conducting through-vias formed in the planarisation layer.

### Organic LED

In the case where the display is an OLED, the device according to the invention comprises a glass or plastic substrate 1 onto which the backplane (not shown) has been formed, an anode 2 and a cathode 4. An electroluminescent layer 3 is provided between anode 2 and cathode 4.

In a practical device, at least one of the electrodes is semi-transparent in order that light may be emitted. Where the anode is transparent, it typically comprises indium tin oxide. Preferably, the cathode is transparent in order to avoid the problem of light emitted from electroluminescent layer 3 being absorbed by the chiplets and other associated drive circuitry in the case where light is emitted through the anode. A transparent cathode typically comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

Suitable materials for use in layer 3 include small molecule, polymeric and dendrimeric materials, and compositions thereof. Suitable electroluminescent polymers for use in layer 3 include poly(arylene vinylenes) such as poly(p-phenylene vinylenes) and polyarylenes such as: polyfluorenes, particularly 2,7-linked 9,9 dialkyl polyfluorenes or 2,7-linked 9,9 diaryl polyfluorenes; polyspirofluorenes, particularly 2,7-linked poly-9,9-spirofluorene; polyindenofluorenes, particularly 2,7-linked polyindenofluorenes; polyphenylenes, particularly alkyl or alkoxy substituted poly-1,4-phenylene. Such polymers as disclosed in, for example, Adv. Mater. 2000 12(23) 1737-1750 and references therein. Suitable electroluminescent dendrimers for use in layer 3 include electroluminescent metal complexes bearing dendrimer c groups as disclosed in, for example, WO 02/066552.

Further layers may be located between anode 2 and cathode 3, such as charge transporting, charge injecting or charge blocking layers.

The device is preferably encapsulated with an encapsulant (not shown) to prevent ingress of moisture and oxygen. Suitable encapsulants include a sheet of glass, films having suitable barrier properties such as alternating stacks of polymer and dielectric as disclosed in, for example, WO 01/81649 or an airtight container as disclosed in, for example, WO 01/19142. A getter material for absorption of any atmospheric moisture and/or oxygen that may permeate through the substrate or encapsulant may be disposed between the substrate and the encapsulant.

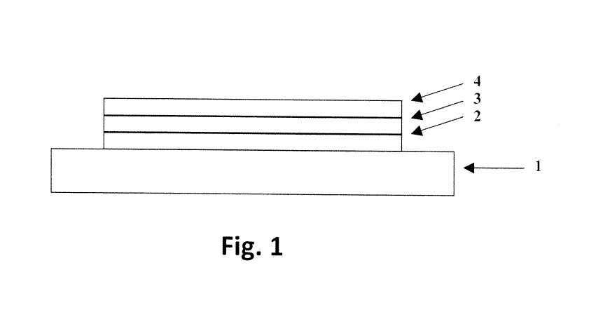

FIG. 1 illustrates a device wherein the device is formed by firstly forming an anode on a substrate followed by deposition of an electroluminescent layer and a cathode, however it will be appreciated that the device of the invention could also be formed by firstly forming a cathode on a substrate followed by deposition of an electroluminescent layer and an anode.

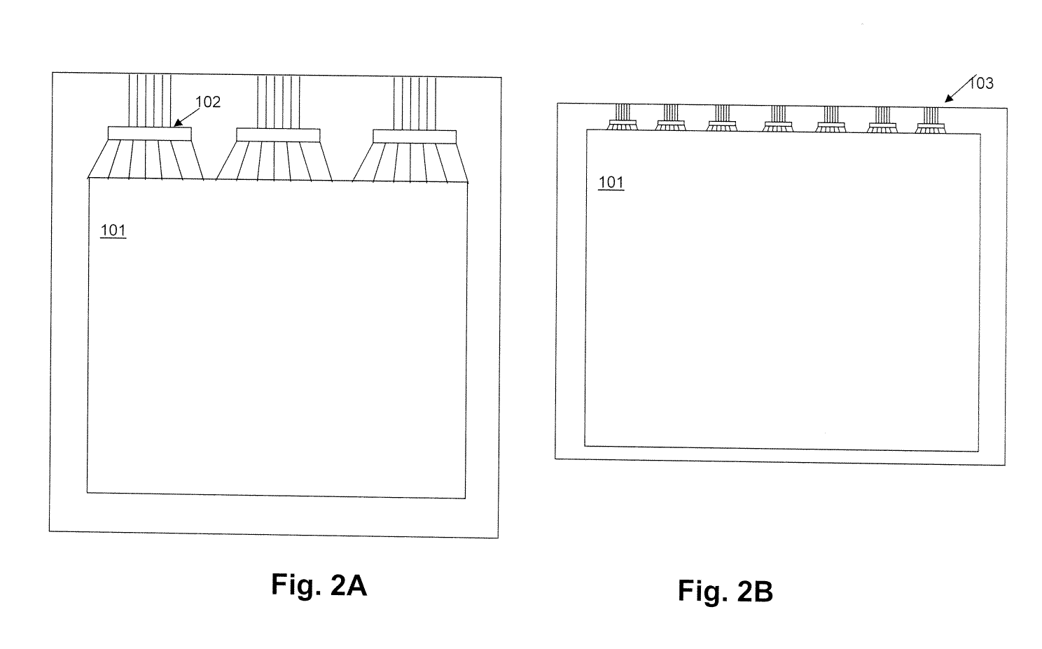

FIG. 2A shows an example of a prior art active matrix display and driving circuitry. As shown, the substrate 101 comprises fan-in and fan-out connections 102 that occupy a large area of the substrate, thus significantly reducing the display area of the substrate.

FIG. 2B shows an active matrix display configuration according to an embodiment of the present invention. As shown, the fan-in and fan-out connections 102 of FIG. 2A comprise a plurality of chiplets 103 outside the active display area 101. This arrangement is advantageous in that the chiplets allow for a much smaller fan-in and fan-out structure, thus allowing a much larger percentage of the substrate to be devoted to display area. Furthermore, encapsulation is improved because the height of the chiplets outside the display area is typically in the micron range, whereas prior art control circuitry arrangements (e.g. of the type shown in FIG. 2A) are typically in the range of several hundred microns to several millimetres in thickness. In this arrangement, the control circuitry is the thickest part of the display and as such is the limiting factor in reducing the display thickness, as well as the overall silicon area. Moreover, use of chiplets is more compatible with flexible displays; although the chiplets themselves are not necessarily flexible, the array of chiplets can be flexed when provided on a flexible substrate.

Those skilled in the art will appreciate that while this disclosure has described what is considered to be the best mode and, where appropriate, other modes of performing the invention, the invention should not be limited to the specific configurations and methods disclosed in this description of the preferred embodiment.

1. A method of manufacturing a control circuit for active matrix display, wherein the control circuit comprises a plurality of chiplets, the method comprising:
positioning the control circuit outside a display area; and
distributing a plurality of outputs of the control circuit to display area drive circuitry among the plurality of chiplets.

2. The method according to claim 1 further comprising a step of patterning the chiplets on an insulator.

3. The method according to claim 2 further comprising a step of transferring the chiplets to a device substrate via a transfer printing process.

4. The method according to claim 3 further comprising a step of bringing the plurality of chiplets into contact with an elastomeric stamp which has surface chemical functionality that causes the chiplets to bind to the stamp, and transferring the chiplets to the device substrate.

5. The method according to claim 1 wherein the drive circuitry comprises amorphous silicon (a-Si) or low-temperature polysilicon (LTPS).

6. The method according to claim 1 wherein the drive circuitry comprises chiplets.

7. An active matrix display comprising:
a display area of the matrix comprising drive circuitry; and,
a control circuit comprising chiplets outside the display area,
wherein the output of the control circuit is distributed among the plurality of chiplets.

8. The display according to claim 7 further comprising an optical sensor for ambient tight detection.
